(19) United States
(12) Patent Application Publication
(10) Pub. No.: US 2023/0170668 A1
(43) Pub. Date: Jun. 1, 2023

(54) DML Driver

(71) Applicant: Nippon Telegraph and Telephone Corporation, Tokyo (JP)

(72) Inventors: Toshiki Kishi, Tokyo (JP); Munehiko Nagatani, Tokyo (JP); Hideyuki Nosaka, Tokyo (JP)

(21) Appl. No.: 17/915,039

(22) PCT Filed: Apr. 7, 2020
(86) PCT No.: PCT/JP2020/015638

§ 371 Date: Sep. 27, 2022

(51) Int. Cl. H01S 5/042

(52) U.S. Cl. CPC H01S 5/042

(57) ABSTRACT

A predriver includes a first transistor for receiving a signal at a gate thereof, a load resistance, a first peaking inductor, a second peaking inductor, a second transistor for receiving a control voltage at a gate thereof, a third transistor for receiving a control voltage at a gate thereof, an inductor for suppressing the group delay, a first peaking capacitor, a second peaking capacitor, and a peaking resistance.

### CROSS-REFERENCE TO RELATED APPLICATIONS

This patent application is a national phase filing under section 371 of PCT application No. PCT/JP2020/015638, filed on Apr. 7, 2020, which is incorporated herein by reference in its entirety.

### TECHNICAL FIELD

The present invention relates to a DML (Directly Modulated Laser) driver for driving a DML.

### BACKGROUND

In recent years, the traffic amount of communication in the world has been increasing year by year due to the remarkable development of SNS (Social Networking Service). Hereafter, a further increase in traffic amount is expected by the development of IOT (Internet of Things) and cloud computing technology. In order to support the massive traffic amount, the increase in communication capacity inside and outside the data center has been demanded.

With an increase in capacity, the standard specification of the Ethernet (registered trademark) of the main standard element of the network has been currently completed in standardization of 10 GbE and 40 GbE, and standardization of 100 GbE aiming for a larger capacity is almost completed. For the purpose of application to 100 GbE, from the viewpoint of the reduction of the power consumption, a driver using a DML has attracted attention (see NPL 1).

Graph (a) of FIG. 10 shows the EO (Electrical-to-Optical) response characteristic of a LD (Laser Diode), and graph (b) of FIG. 10 shows the group delay characteristic of a LD. As shown in FIG. 10, the relaxation oscillation frequency fᵣ of the LD causes an increase in group delay in the vicinity of fᵣ. For this reason, with a driver for driving such a LD, even when the frequency band is improved using a simple frequency peaking method, there is a problem that the group delay undesirably increases.

### CITATION LIST

### Non Patent Literature

[NPL 1] A. Moto, T. Ikagawa, S. Sato, Y. Yamasaki, Y. Onishi, and K. Tanaka, “A low power quad 25.78-Gbit/s 2.5 V laser diode driver using shunt-driving in 0.18 μm SiGe-BiCMOS”, Compound Semiconductor Integrated Circuit Symposium, 2013.

### SUMMARY

### Technical Problem

Embodiments of the present invention were completed in order to solve the problem. It is an embodiment of the present invention to provide a DML driver capable of improving the band of the EO response characteristic while suppressing the group delay in the vicinity of the relaxation oscillation frequency of a LD.

### Means for Solving the Problem

A DML driver of embodiments of the present invention includes a first transistor for receiving a signal at a gate or a base thereof; a first resistance connected at one end thereof with a first power supply voltage; a first inductor connected at one end thereof with the other end of the first resistance, and connected at the other end thereof with a drain or a collector of the first transistor; a second inductor connected at one end thereof with the drain or the collector of the first transistor, and connected at the other end thereof with an input terminal of a post driver for supplying a driving current to a laser diode; a second transistor for receiving a first control voltage at a gate or a base thereof, connected at a source or an emitter thereof with the first power supply voltage, and connected at a drain or a collector thereof with a node between the first resistance and the first inductor; a third transistor for receiving a second control voltage at a gate or a base thereof, connected at a drain or a collector thereof with a source or an emitter of the first transistor, and connected at a source or an emitter thereof with a second power supply voltage; a third inductor connected at one end thereof with a drain or a collector of the third transistor, and connected at the other end thereof with the second power supply voltage; a first capacitor connected at one end thereof with a drain or a collector of the third transistor, and connected at the other end thereof with the second power supply voltage; a second capacitor connected at one end thereof with a drain or a collector of the third transistor; and a second resistance connected at one end thereof with the other end of the second capacitor, and connected at the other end thereof with the second power supply voltage.

### Effects of Embodiments of the Invention

In accordance with embodiments of the present invention, a first transistor is provided with first and second resistances, first to third inductors, and first and second capacitors. This can add an equalizer function of suppressing the group delay in the vicinity of the relaxation oscillation frequency of the laser diode, and a peaking function of performing improvement of the band to the DML driver. This enables the suppression of the group delay in the vicinity of the relaxation oscillation frequency, and further the improvement of the band of the EO response characteristic. Further, in embodiments of the present invention, the second transistor is provided in parallel with the first resistance, and the third transistor is provided in parallel with the first capacitor. As a result, the first and second control voltages can adjust the peaking amount of the EO response characteristic.

### BRIEF DESCRIPTION OF THE DRAWINGS

FIG. 1 is a circuit diagram showing a configuration of a DML driver in accordance with an embodiment of the present invention.

FIG. 2 is a view showing the parasitic capacitances of a post driver and a predriver of FIG. 1.

FIG. 3 is a view for illustrating the effect of the DML driver in accordance with an embodiment of the present invention.

FIG. 4 is a view for illustrating the effect of the equalizer adjusting function of the DML driver in accordance with an embodiment of the present invention.

FIG. 5 is a view showing the optical output waveform of a LD single body.

FIG. 6 is a view showing the optical output waveform in the case where the DML driver in accordance with an embodiment of the present invention and the LD are merged.

FIG. 7 is a circuit diagram showing the configuration of a DML driver in accordance with another embodiment of the present invention.

FIG. 8 is a circuit diagram showing the configuration of a DML driver in accordance with another embodiment of the present invention.

FIG. 9 is a circuit diagram showing the configuration of a DML driver in accordance with another embodiment of the present invention.

FIG. 10 is a view showing the EO response characteristic and the group delay characteristic of a LD.

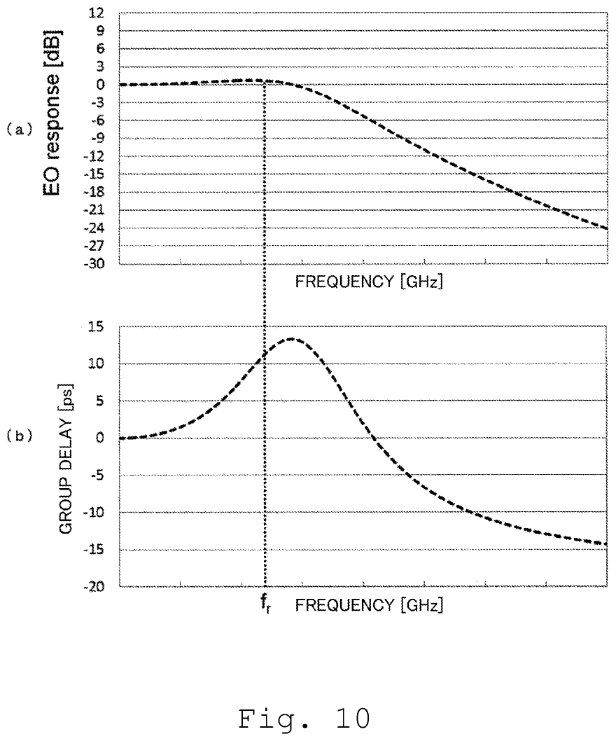

### DETAILED DESCRIPTION OF ILLUSTRATIVE EMBODIMENTS

### First Embodiment

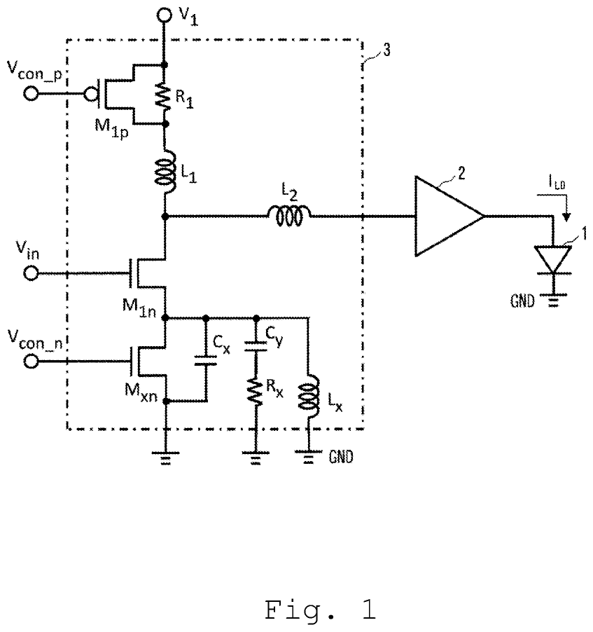

Below, embodiments of the present invention will be described by reference to the accompanying drawings. FIG. 1 is a circuit diagram showing a configuration of a DML driver in accordance with an embodiment of the present invention. The DML driver of the present embodiment includes a post driver 2 for supplying a driving current I_{LD} to a LD 1, and a predriver 3 for driving the post driver 2 in response to an inputted modulation signal Vᵢₙ.

The post driver 2 is assumed to be a driver including a transistor (not shown), and capable of driving the LD 1. In embodiments of the present invention, to the post driver 2, a driver circuit with a given configuration is applicable.

The predriver 3 has an equalizer function of suppressing the group delay in the vicinity of the relaxation oscillation frequency fᵣ of the LD 1, and a peaking function of performing improvement of the band. Specifically, the predriver 3 includes an NMOS transistor M₁ₙ for receiving a modulation signal Vᵢₙ at the gate, a load resistance R₁ connected at one end thereof with a power supply voltage V₁ (first power supply voltage), a peaking inductor L₁ connected at one end thereof with the other end of the load resistance R₁, and connected at the other end thereof with the drain of the transistor M₁ₙ, a peaking inductor L₂ connected at one end thereof with the drain of the transistor M₁ₙ, and connected at the other end thereof with the input terminal of the post driver 2, a PMOS transistor M₁ₚ for receiving a control voltage V_{con_p} (first control voltage) at the gate thereof, connected with the power supply voltage V₁ at the source thereof, and connected with the node between the load resistance R₁ and the peaking inductor L₁ at the drain thereof, an NMOS transistor Mₓₙ for receiving a control voltage V_{con_n} (second control voltage) at the gate, connected with the source of the transistor M₁ₙ at the drain thereof, and connected with a grounding voltage GND (a second power supply voltage lower than the first power supply voltage) at the source, an inductor Lₓ for suppressing the group delay connected at one end thereof with the drain of the transistor Mₓₙ, and connected at the other end thereof with the grounding voltage GND, a peaking capacitor Cₓ connected at one end thereof with the drain of the transistor Mₓₙ, and connected at the other end thereof with the grounding voltage GND, a peaking capacitor C_{y} connected at one end thereof with the drain of the transistor Mₓₙ, and a peaking resistance Rₓ connected at one end thereof with the other end of the peaking capacitor C_{y}, and connected at the other end thereof with the grounding voltage GND.

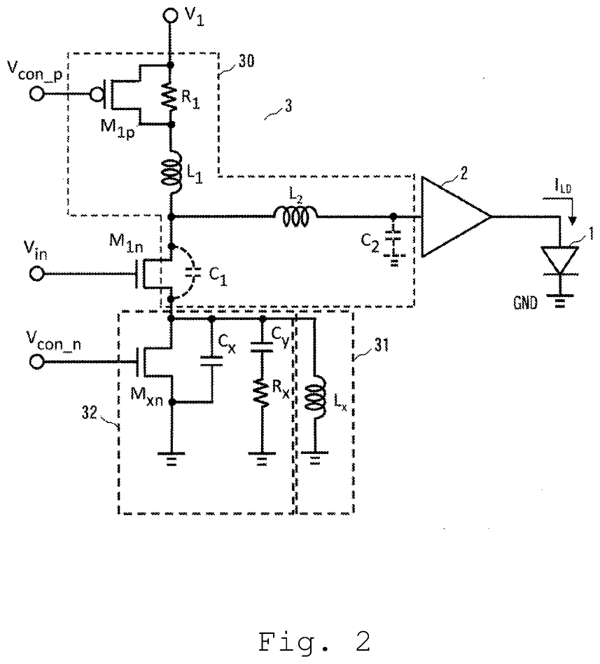

FIG. 2 is a view showing the parasitic capacitances of the post driver 2 and the predriver 3 shown in FIG. 1. C₁ is the parasitic capacitance of the transistor M₁ₙ, and C₂ is the parasitic capacitance of the transistor (not shown) of the input part of the post driver 2. The parasitic capacitance C₁ is the parasitic capacitance between drain-source when the transistor M₁ₙ is a FET, and is the parasitic capacitance between collector-emitter when the transistor M₁ₙ is a bipolar transistor. When the transconductance of the transistor M₁ₙ is set at gₘ, the gain Av of the predriver 3 can be expressed by Equation (1) using the following Laplace function.

$$\begin{matrix}Equation ( 1 ) & \\ \vert {A}_{v} ( s ) \vert = \frac{{C}_{x} s + \frac{1}{{L}_{x} s} + \frac{1}{{R}_{x} + \frac{1}{{C}_{y} s}}}{{C}_{2} s + \frac{1}{{L}_{2} s + \frac{1}{{C}_{1} s + \frac{1}{{R}_{1} + {L}_{1} s}}}} {g}_{m} & ( 1 )\end{matrix}$$

The s in Equation (1) is the Laplace operator. The part 30 of FIG. 2 including the load resistance R₁ and the peaking inductors L₁ and L₂ forms the peaking function part. At the peaking function part 30, the larger the values of the load resistance R₁ and the peaking inductors L₁ and L₂ are, the larger the peaking amount of the EO response characteristic becomes. Further, the smaller the parasitic capacitances C₁ and C₂ are, the larger the peaking amount becomes.

Further, for the load impedance between V₁-L₁, the PMOS transistor M₁ₚ is connected in parallel with the load resistance R₁. When the control voltage V_{con_p} to be inputted to the gate of the PMOS transistor M₁ₚ is increased, the transistor M₁ₚ is put in an OFF state, and the load impedance becomes R₁. Conversely, when the control voltage V_{con_p} is decreased, the transistor M₁ₚ is put in an ON state, and the load impedance becomes the impedance value in parallel with the ON resistance of the transistor M₁ₚ and the load resistance R₁, and becomes a smaller value than R₁. In other words, it becomes possible to adjust the peaking amount of the EO response characteristic by the control voltage V_{con_p}.

The part 31 of FIG. 2 including the inductor Lₓ forms the group delay suppressing function part. The inductor Lx can suppress the peak of the group delay amount in the vicinity of the relaxation oscillation frequency fᵣ of the LD 1.

The part 32 of FIG. 2 including the peaking capacitors Cₓ and C_{y} and the peaking resistance Rₓ forms the peaking function part in the high region. The peaking function part 32 can suppress the reduction of the group delay amount of the LD 1 in the high region and the reduction of the group delay amount of the inductor Lₓ.

Further, the control voltage V_{con_n} to be inputted to the gate of the NMOS transistor Mₓ connected in parallel with the peaking capacitor Cₓ can adjust the peaking amount in the high region of the EO response characteristic. For example, when the control voltage V_{con_n} is decreased, the transistor Mₓ is put into an OFF state, resulting in a high impedance between drain-source of the transistor Mₓₙ. Whereas, when the control voltage V_{con_n} is increased, the transistor Mₓₙ is put into an ON state, resulting in a low impedance between drain-source of the transistor Mₓₙ.

When a high impedance is caused between drain-source of the transistor Mₓₙ, the impedance in parallel with the transistor Mₓₙ and the capacitor Cₓ is also increased. For this reason, the peaking amount in the high region by the peaking function part 32 is suppressed. Conversely, when a low impedance is caused between drain-source of the transistor Mₓₙ, the impedance in parallel with the transistor Mₓₙ and the capacitor Cₓ is also reduced, resulting in an increase in peaking amount in the high region.

The peaking function parts 30 and 32 and the group delay suppressing function part 31 can implement the equalizer function. Even when a difference is caused in frequency characteristic among individual LD 1's, the adjustment of the control voltages V_{con_n} and V_{con_p} can adjust the equalizer according to each individual LD 1.

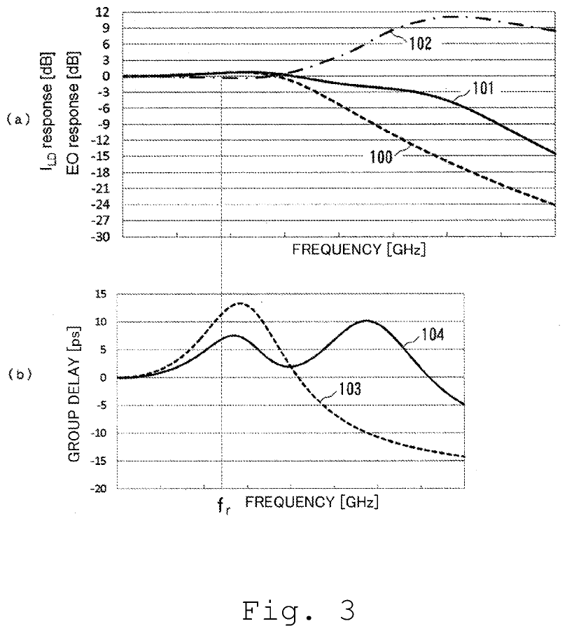

FIG. 3 is a view for illustrating the effect of the DML driver of the present embodiment. Line 100 in graph (a) of FIG. 3 represents the EO response characteristic of the LD 1 single body, and line 101 represents the EO response characteristic of the combination of the DML driver and the LD 1 of the present embodiment. Line 102 represents the transmission characteristic in the injection current I_{LD} to the LD 1. Further, line 103 in graph (b) of FIG. 3 represents the group delay characteristic of the LD 1 single body, and line 104 represents the group delay characteristic of the combination of the DML driver and the LD 1 of the present embodiment.

The peaking function parts 30 and 32 and the group delay suppressing function part 31 can improve the band of the EO response characteristic without increasing the resonant peak of the EO response characteristic as shown in FIG. 3. This enables suppression of the group delay as shown in FIG. 3.

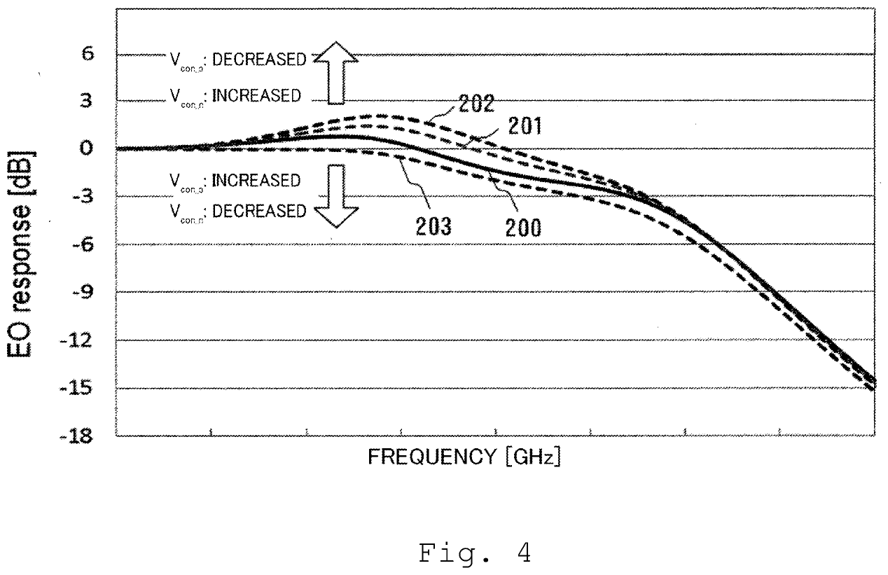

FIG. 4 is a view for illustrating the effect of the equalizer adjusting function of the DML driver of the present embodiment. Line 200 of FIG. 4 represents the EO response characteristic of the combination of the DML driver and the LD 1 when the control voltages V_{con_p} and V_{con_n} are set at given voltage values, respectively. Lines 201 and 202 of FIG. 4 represent the EO response characteristics of the combination of the DML driver and the LD 1 when the control voltage V_{con_p} is decreased and the control voltage V_{con_n} is increased relative to the case of line 200. Line 203 of FIG. 4 represents the EO response characteristic of the combination of the DML driver and the LD 1 when the control voltage V_{con_p} is increased and the control voltage V_{con_n} is decreased relative to the case of line 200. FIG. 4 indicates that the adjustment of the control voltages V_{con_p} and V_{con_n} can adjust the peaking amount as described up to this point.

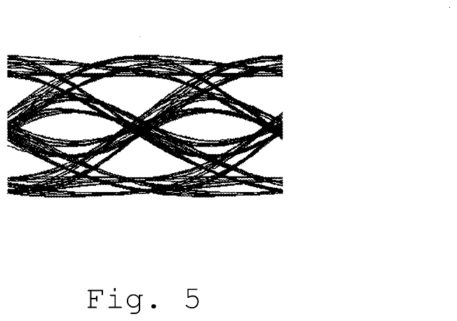

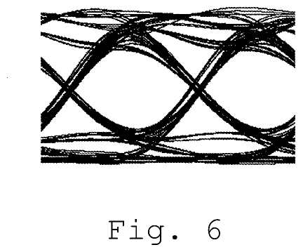

FIG. 5 is a view showing the results determined by simulating the optical output waveform of the LD 1 single body. FIG. 6 is a view showing the results determined by simulating the optical output waveform when the DML driver of the present embodiment and the LD 1 are combined. FIGS. 5 and 6 indicate that the eye opening is improved by the DML driver of the present embodiment.

### Second Embodiment

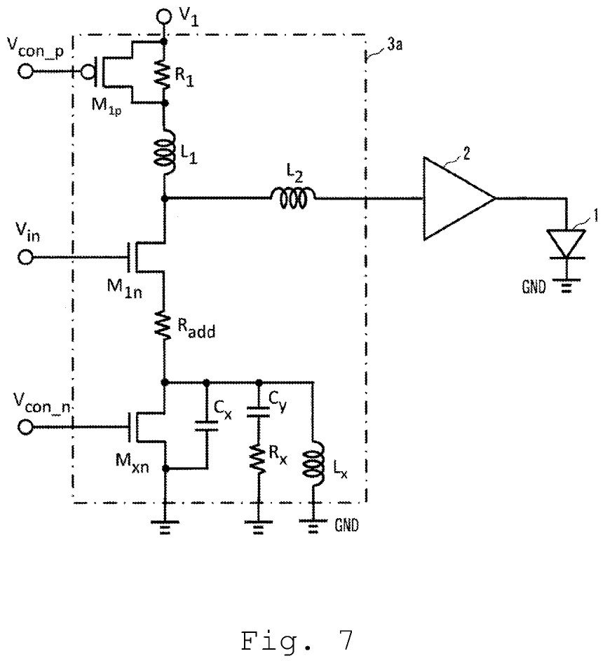

A second Embodiment of the present invention will be described. FIG. 7 is a circuit diagram showing a configuration of a DML driver in accordance with the second embodiment of the present invention, where the same configuration as that of FIG. 1 is given the same reference numerals and signs. The DML driver of the present embodiment includes a post driver 2 and a predriver 3a.

The predriver 3a of the present embodiment includes a resistance R_{add} inserted between the source of the transistor M₁ₙ and the drain of the transistor Mₓₙ in the predriver 3 of the first embodiment. Thus, in the present embodiment, the linearization function can be added to the predriver 3a. When the post driver 2 also has the linearization function, it becomes possible to drive the LD 1 even when the signal Vᵢₙ to be inputted to the predriver 3a is a signal required to have linearity such as a PAM (Pulse Amplitude Modulation) signal or a DMT (Discrete MultiTone) signal.

### Third Embodiment

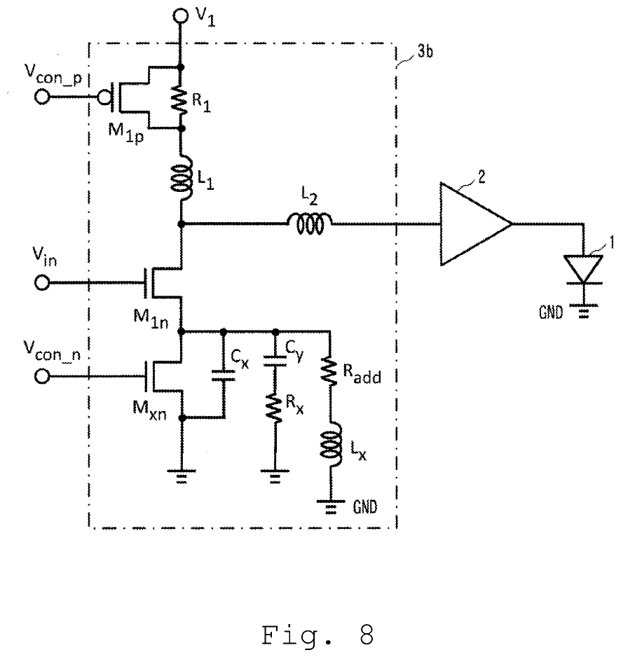

A third embodiment of the present invention will be described. FIG. 8 is a circuit diagram showing a configuration of a DML driver in accordance with the third embodiment of the present invention, where the same configuration as that of FIG. 1 is given the same reference numerals and signs. The DML driver of the present embodiment includes a post driver 2 and a predriver 3b.

The predriver 3b of the present embodiment includes a resistance R_{add} inserted between the drain of the transistor Mₓₙ and one end of the inductor Lₓ in the predriver 3 of the first embodiment. In the present embodiment, as compared with the configuration of the second embodiment, it is possible to reduce the impedance added to the source of the transistor M₁ₙ in the high region, and it is possible to increase the gain of the driver. For this reason, it becomes possible to improve the frequency band.

### Fourth Embodiment

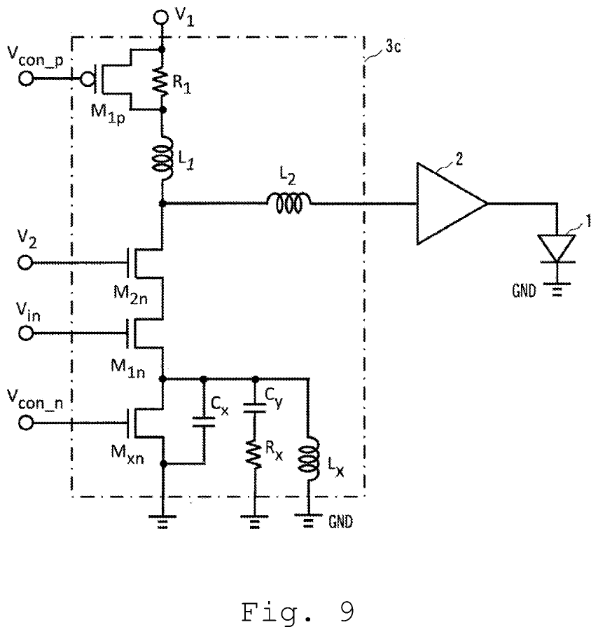

A fourth embodiment of the present invention will be described. FIG. 9 is a circuit diagram showing the configuration of a DML driver in accordance with the fourth embodiment of the present invention, where the same configuration as that of FIG. 1 is given the same reference numerals and signs. The DML driver of the present embodiment includes a post driver 2 and a predriver 3c.

The predriver 3c of the present embodiment includes an NMOS transistor M₂ₙ, in which a direct-current bias voltage V₂ is inputted to the gate, the drain is connected with the node of the inductors L₁ and L₂, and the source is connected with the drain of the transistor M₁ₙ, inserted in the predriver 3 of the first embodiment. The bias voltage V₂ is desirably set so that the transistors M₁ₙ and M₂ₙ operate in the saturation region.

In the present embodiment, the transistors M₁ₙ and M₂ₙ are connected in a cascode type, which can suppress the mirror effect in the transistor M₁ₙ. For this reason, it is possible to further improve the frequency characteristic of the DML driver.

Incidentally, in the first to fourth embodiments, the examples were shown in which a FET was used as the transistor M₁ₙ, M₂ₙ, Mₓₙ, or M₁ₚ. However, it is also acceptable that a NPN bipolar transistor is used as the transistor M₁ₙ, M₂ₙ, or Mₓₙ, and a PNP bipolar transistor is used as the transistor M₁ₚ. When a bipolar transistor is used, in the description in the first to fourth embodiments, it is essential only that the gate is replaced with the base, the drain is replaced with the collector, and the source is replaced with the emitter.

### INDUSTRIAL APPLICABILITY

Embodiments of the present invention are applicable to the technology of directly modulating the optical output of a LD.

### REFERENCE SIGNS LIST

1 Laser diode
2 Post driver
3, 3a, 3b, 3c Predriver
M₁ₙ, M₂ₙ, Mₓₙ, M₁ₚ Transistor
R₁, Rₓ, R_{add} Resistance
L₁, L₂, Lₓ Inductor
Cₓ, C_{y} Capacitor
30, 32 Peaking function part
31 Group delay suppressing function part

1-4. (canceled)

5. A DML driver comprising:
a first transistor configured to receive a first signal at a gate thereof;
a first resistance connected at a first end thereof with a first power supply voltage;
a first inductor connected at a first end thereof with a second end of the first resistance and connected at a second end thereof with a drain of the first transistor;
a second inductor connected at a first end thereof with the drain of the first transistor and connected at a second end thereof with an input terminal of a post driver to supply a driving current to a laser diode;
a second transistor configured to receive a first control voltage at a gate thereof, connected at a source thereof with the first power supply voltage, and connected at a drain thereof with a node between the first resistance and the first inductor;
a third transistor configured to receive a second control voltage at a gate thereof, connected at a drain thereof with a source of the first transistor, and connected at a source thereof with a second power supply voltage;
a third inductor connected at a first end thereof with a drain of the third transistor and connected at a second end thereof with the second power supply voltage;
a first capacitor connected at a first end thereof with a drain of the third transistor and connected at a second end thereof with the second power supply voltage;
a second capacitor connected at a first end thereof with a drain of the third transistor; and
a second resistance connected at a first end thereof with a second end of the second capacitor and connected at a second end thereof with the second power supply voltage.

6. The DML driver according to claim 5, further comprising a third resistance inserted between the source of the first transistor and the drain of the third transistor.

7. The DML driver according to claim 5, further comprising a third resistance inserted between the drain of the third transistor and the first end of the third inductor.

8. The DML driver according to claim 5, further comprising a fourth transistor inserted between a node between the first and second inductors and the drain of the first transistor to receive a bias voltage at a gate thereof, connected at a drain thereof with the node between the first and second inductors, and connected at a source thereof with the drain of the first transistor.

9. A DML driver comprising:
a first transistor configured to receive a first signal at a base thereof;
a first resistance connected at a first end thereof with a first power supply voltage;
a first inductor connected at a first end thereof with a second end of the first resistance and connected at a second end thereof with a collector of the first transistor;
a second inductor connected at a first end thereof with the collector of the first transistor and connected at a second end thereof with an input terminal of a post driver to supply a driving current to a laser diode;
a second transistor configured to receive a first control voltage at a base thereof, connected at an emitter thereof with the first power supply voltage, and connected at a collector thereof with a node between the first resistance and the first inductor;
a third transistor configured to receive a second control voltage at a base thereof, connected at a collector thereof with an emitter of the first transistor, and connected at an emitter thereof with a second power supply voltage;
a third inductor connected at a first end thereof with a collector of the third transistor and connected at a second end thereof with the second power supply voltage;
a first capacitor connected at a first end thereof with a collector of the third transistor and connected at a second end thereof with the second power supply voltage;
a second capacitor connected at a first end thereof with a collector of the third transistor; and
a second resistance connected at a first end thereof with a second end of the second capacitor and connected at a second end thereof with the second power supply voltage.

10. The DML driver according to claim 9, further comprising a third resistance inserted between the emitter of the first transistor and the collector of the third transistor.

11. The DML driver according to claim 9, further comprising a third resistance inserted between the collector of the third transistor and the first end of the third inductor.

12. The DML driver according to claim 9, further comprising a fourth transistor inserted between a node between the first and second inductors and the collector of the first transistor to receive a bias voltage at a base thereof, connected at a collector thereof with the node between the first and second inductors, and connected at an emitter thereof with the collector of the first transistor.

13. A method of arranging a DML driver, the method comprising:
providing a first transistor comprising a gate at which a first signal is received;
connecting a first end of a first resistance with a first power supply voltage;
connecting a first end of a first inductor with a second end of the first resistance and connecting a second end of the first inductor with a drain of the first transistor;
connecting a first end of a second inductor with the drain of the first transistor and connecting a second end of the second inductor with an input terminal of a post driver to supply a driving current to a laser diode;
connecting a source of a second transistor with the first power supply voltage and connecting a drain of the second transistor with a node between the first resistance and the first inductor, wherein the second transistor comprises a gate at which a first control voltage is received;
connecting a drain of a third transistor with a source of the first transistor and connecting a source of the third transistor with a second power supply voltage, wherein the third transistor comprises a gate at which a second control voltage is received;
connecting a first end of a third inductor with a drain of the third transistor and connecting a second end of the third inductor with the second power supply voltage;
connecting a first end of a first capacitor with a drain of the third transistor and connecting a second end of the first capacitor with the second power supply voltage;
connecting a first end of a second capacitor with a drain of the third transistor; and
connecting a first end of a second resistance with a second end of the second capacitor and connecting a second end of the second resistance with the second power supply voltage.

14. The method according to claim 13, further comprising inserting a third resistance between the source of the first transistor and the drain of the third transistor.

15. The method according to claim 13, further comprising inserting a third resistance between the drain of the third transistor and the first end of the third inductor.

16. The method according to claim 13, further comprising:
inserting a fourth transistor between a node between the first and second inductors and the drain of the first transistor to receive a bias voltage at a gate thereof;
connecting a drain of the fourth transistor with the node between the first and second inductors; and
connecting a source of the fourth transistor with the drain of the first transistor.
